(19) United States
(12) Patent Application Publication
(10) Pub. No.: US 2026/0262353 A1
(43) Pub. Date: Sep. 3, 2026

(54) APPARATUS AND METHOD FOR TRANSFERRING LIGHT-EMITTING DIODES

(71) Applicant: SAMSUNG ELECTRONICS CO., LTD., Suwon-si (KR)

(72) Inventors: Ivan HUANG, Milpitas, CA (US); Eric STRASILLA, Milpitas, CA (US); Ansel REED, Milpitas, CA (US)

(73) Assignee: SAMSUNG ELECTRONICS CO., LTD., Suwon-si (KR)

(21) Appl. No.: 18/840,694

(22) PCT Filed: Feb. 21, 2023
(86) PCT No.: PCT/US2023/013511

§ 371 Date: Aug. 22, 2024

Related U.S. Application Data
(60) Provisional application No. 63/312,701, filed on Feb. 22, 2022.

(51) Int. Cl. H10H 29/03; H10H 29/01; H10H 29/24; H10H 29/85

(52) U.S. Cl. CPC H10H 29/03; H10H 29/0364; H10H 29/24; H10H 29/857

(57) ABSTRACT

A method includes placing a work piece in an apparatus containing first support structure and a second support structure such that the work piece is located between the first support structure and the second support structure, generating a pressure on a portion of the work piece by actuating a movable member that presses on the work piece from a first side of the work piece to generate a first force on a first side of the work piece that presses a second side of the work piece against an optically transparent mechanical stop, and directing laser radiation through the optically transparent mechanical stop to irradiate the portion of the work piece.

### FIELD

The embodiments of the invention are directed generally to an apparatus for transferring light-emitting diodes (LEDs), and a method of transferring LEDs that includes drawing a vacuum on a space such that a transparent panel presses a plurality of LED coupons toward a backplane.

### BACKGROUND

Light emitting diodes (LEDs) are used in electronic displays, such as liquid crystal displays in laptops, LED televisions, direct view displays, micro displays or heads up displays. However, it is challenging to attach LEDs to a backplane (e.g., display backplane) with a high yield.

### SUMMARY

According to an aspect of the present disclosure, an apparatus comprises a rigid structure comprising a first structural member supported above a second structural member thereby forming an open channel, an optically transparent mechanical stop supported by the first structural member, at least one laser radiation source positioned to provide laser radiation through the optically transparent mechanical stop, and a movable member supported by the second structural member. The rigid structure is configured to receive a work piece in the open channel and to clamp the work piece by generating a pressure on the movable member such that the movable member presses on the work piece from a first side of the work piece to generate a first force on the first side of the work piece that presses a second side of the work piece against the optically transparent mechanical stop.

According to another aspect of the present disclosure, a method includes placing a work piece in an apparatus containing first support structure and a second support structure such that the work piece is located between the first support structure and the second support structure, generating a pressure on a portion of the work piece by actuating a movable member that presses on the work piece from a first side of the work piece to generate a first force on a first side of the work piece that presses a second side of the work piece against an optically transparent mechanical stop, and directing laser radiation through the optically transparent mechanical stop to irradiate the portion of the work piece.

### BRIEF DESCRIPTION OF THE DRAWINGS

FIG. 1 illustrates a top view of LED coupon (e.g., first source coupon) 1 containing a growth substrate 8 including dies of LEDs 10, according to some embodiments.

FIG. 2 illustrates a side cross-sectional view of the LED coupon 1, according to some embodiments,

FIG. 3 illustrates a side cross-sectional view of an arrangement of the LED coupon 1 in preparation of transferring the LEDs 10A, 10B, 10C from the LED coupon 1 to a backplane 32, according to some embodiments.

FIG. 4A illustrates a side cross-sectional view of an apparatus 400 that may be used to transfer the LEDs 10A, 10B, 10C from the LED coupon 1 to the backplane 32, according to some embodiments.

FIG. 4B illustrates a side cross-sectional view of the apparatus 400 after the pulling of a vacuum on the space S by the vacuum source 440, according to some embodiments.

FIG. 5 illustrates a side a cross-sectional view of an apparatus 450 for transferring LEDs according to some embodiments.

FIG. 6A illustrates a side a cross-sectional view of the backplane 32 placed on a backing board 410, the LED coupon 1 placed on the backplane 32, and the transparent panel 430 placed on the LED coupon 1, according to some embodiments.

FIG. 6B illustrates a side a cross-sectional view of a sequential laser irradiation process performed to irradiate buffer layer 11 of the LED 10A that is to be transferred to the backplane 32 with a detachment laser beam LD, according to some embodiments.

FIG. 6C illustrates a side a cross-sectional view of the liquid gallium-rich drops 111 solidifying into solid gallium-rich material portions (e.g., pure gallium or gallium rich alloy particles or regions) 211 after the irradiation, according to some embodiments.

FIG. 6D illustrates a side a cross-sectional view of the backplane 32 and the LED coupon 1 pressed against each other to induce deformation of the bonding material portions (17, 37), according to some embodiments.

FIG. 6E illustrates a side a cross-sectional view of localized laser irradiation process performed to induce reflow and bonding of the mating pair of a diode-side bonding material portion 17 and a backplane-side bonding material portion 37 that underlies the LED 10A, according to some embodiments.

FIG. 6F illustrates a side a cross-sectional view of the vacuum source 440 ceasing to draw a vacuum on the space S between the backplane 32 and the LED coupon 1, so that the transparent panel 430 stops applying a downward pressure on the LED coupon 1, according to some embodiments.

FIG. 7A is a three dimensional perspective view of a component of an apparatus for transferring LEDs, according to some embodiments.

FIG. 7B illustrates a side a cross-sectional view of a portion of the component shown in FIG. 7A with the bladder inflated, according to some embodiments.

FIG. 7C illustrates a side a cross-sectional view of a portion of the component shown in FIG. 7A with the bladder deflated, according to some embodiments.

FIG. 7D illustrates top view of a the movable member of the component shown in FIG. 7A, according to some embodiments.

FIG. 8 is a top view of the an apparatus containing the component of FIG. 7A, according to some embodiments.

FIG. 9 is a three-dimensional perspective view of the apparatus of FIG. 8, which further includes a movable stage, according to some embodiments.

FIG. 10 is a vertical cross-sectional view of a portion of a pin release mechanism, according to some embodiments.

FIG. 11 is a vertical cross-sectional view of a further apparatus for transferring light-emitting diodes, according to some embodiments.

FIG. 12 illustrates a flowchart that illustrates various operations in a method of transferring LEDs, according to some embodiments.

### DETAILED DESCRIPTION

The embodiments of the present disclosure are directed to an apparatus and method for transferring LEDs, the various aspects of which are described below. Throughout the drawings, like elements are described by the same reference numeral. Elements with the same reference numeral are presumed to have a same material composition unless expressly stated otherwise. The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure.

An LED may be a vertical structure (e.g., a vertical LED) in which the p-side and n-side contacts are located on opposite sides of the structure or a lateral structure in which the p-side and n-side contacts are located on the same side of the structure. In the embodiments of the present disclosure, a method is provided for transferring LEDs (e.g., an array of LEDs) from a growth substrate to a target substrate, such as a backplane. In an illustrative example, the target substrate can be a backplane such as an active or passive matrix backplane substrate for driving LEDs. As used herein, a “backplane” refers to any substrate configured to affix multiple LEDs thereupon.

The LEDs may include different “types” such as red LEDs which emit red light, green LEDs which emit green light and blue LEDs which emit blue light. LEDs of the same type may be fabricated on respective growth substrates (e.g., initial growth substrates). In particular, LEDs may be fabricated as an array on growth substrates that are processed to form various electronic devices thereupon or therein, including LEDs, sensor devices (e.g., photodetectors), etc. The LEDs may be for example, vertical LEDs, lateral LEDs, or any combination thereof.

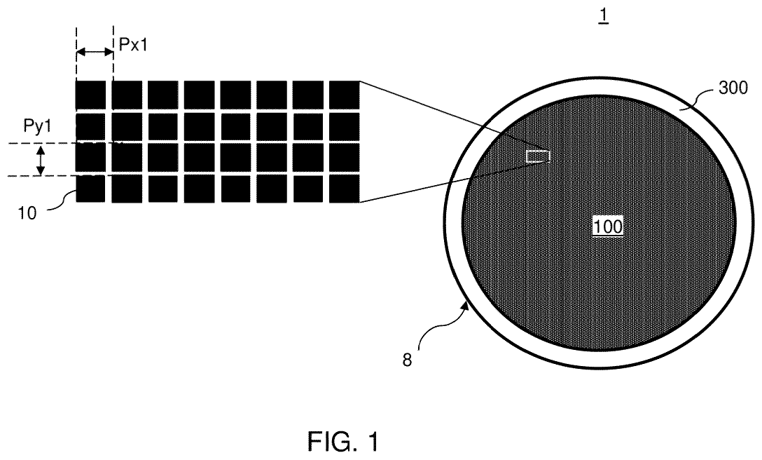

Referring to FIG. 1, an LED coupon (e.g., first source coupon) 1 containing a growth substrate 8 including dies of LEDs 10 is illustrated. The growth substrate 8 may include an edge exclusion region 300 at a periphery, in which LEDs 10 are not formed. The growth substrate 8 can include LEDs of a same type (e.g., red LEDs, green LEDs, blue LEDs, etc.) arranged in a first array 100. That is, the LEDs 10 may include multiple instances of the same type LED, which may be, for example, light emitting diodes that emit light at a same peak wavelength.

The first array 100 has a primary-direction pitch Px1 along a respective primary direction (i.e., the primary direction of the first array 100) and has a secondary-direction pitch Py1 along a respective secondary direction (i.e., the secondary direction of the first array 100). As used herein, a primary direction and a second direction of an array refer to two directions along which a unit cell of the array is repeated. In a rectangular array, the primary direction and the second direction may be perpendicular to each other, and are referred to as an x-direction and a y-direction.

The LEDs 10 on the growth substrate 8 can be transferred to one or more backplanes having bonding sites configured in a second array. A predetermined transfer pattern and a predetermined transfer sequence can be employed for transfer of the LEDs 10. LEDs of different types (e.g., green LEDs and blue LEDs) transferred from different growth substrates can be employed in conjunction with the LEDs 10 (e.g., red LEDs) to provide a functional direct view LED assembly.

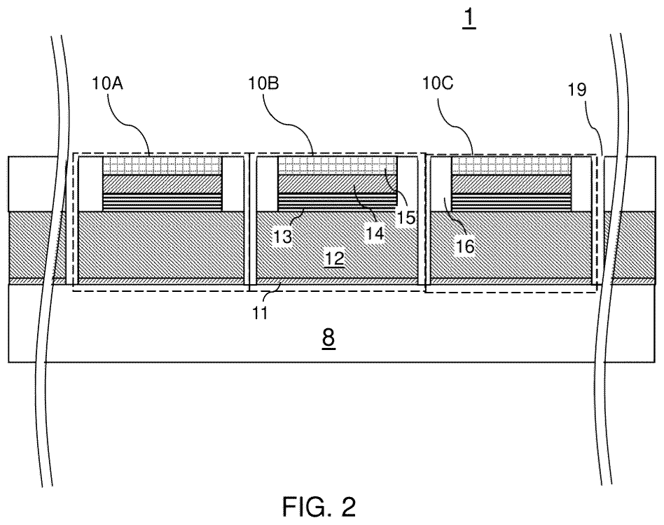

FIG. 2 illustrates a cross-sectional view of the LED coupon 1, according to some embodiments. As illustrated in FIG. 2, the LED coupon 1 includes the growth substrate 8 and a plurality of LEDs 10A, 10B, 10C located on the growth substrate 8. The growth substrate 8 may be any suitable substrate on which LED layers may be grown, such as a single crystalline substrate on which LED semiconductor layers can be grown. For example, the growth substrate 8 may include a sapphire substrate.

The LEDs 10A, 10B, 10C may include a buffer layer 11 and a first conductivity type semiconductor layer 12. The buffer layer 11 may include an amorphous III-V compound semiconductor layer that includes gallium and nitrogen. The first conductivity type semiconductor layer 12 may include a crystalline III-V compound semiconductor material layer that includes gallium and nitrogen. For example, the buffer layer 11 may include amorphous gallium nitride (GaN), indium gallium nitride (InGaN), aluminum gallium nitride (AlGaN) or aluminum indium gallium nitride (AlInGaN), while the first conductivity type semiconductor layer 12 may include single crystalline or polycrystalline GaN, InGaN, AlGaN or AlInGaN. The first conductivity type semiconductor layer 12 may have conductivity of the first type, which may be n-type or p-type. For example, the first conductivity type semiconductor layer 12 may include an n-type semiconductor layer. The buffer layer 11 may be undoped or may also have the first conductivity type.

The buffer layer 11 is located between the first conductivity type semiconductor layer 12 and the growth substrate 8. The buffer layer 11 may have the same material composition as the first conductivity type semiconductor layer 12.

For example, in one embodiment, the buffer layer 11 and the first conductivity type semiconductor layer 12 may both comprise gallium nitride. In this case, the buffer layer 11 may be formed during the initial deposition of crystalline gallium nitride first conductivity type semiconductor layer 12 on growth substrate 8 which may be a patterned sapphire substrate (PSS) in this embodiment. That is, the buffer layer 11 may be formed as the gallium nitride growth conditions transition from the amorphous to crystalline gallium nitride layer growth. The thickness of the buffer layer 11 can be in a range from 100 nm to 400 nm, such as from 150 nm to 300 nm, although lesser and greater thicknesses can also be employed. The thickness of the first conductivity type semiconductor layer 12 can be from 500 nm to 5 microns, such as 1 to 3 microns, although lesser and greater thicknesses can also be employed.

An active layer 13 may be formed over the first conductivity type semiconductor layer 12. In one embodiment, the active layer 13 may comprise at least one bulk, quasi-bulk or quantum well layer selected from GaN, InGaN, AlGaN and/or AlInGaN. For example, the active layer 13 may comprise a stack of one or more InGaN quantum well layers between respective GaN and/or AlGaN barrier layers. Generally, any light emitting layer stack known in the art can be employed for the active layer 13.

A second conductivity type semiconductor layer 14 may be formed over the active layer 13. The second conductivity type semiconductor layer 14 may have a doping of a second conductivity type. The second conductivity type is the opposite of the first conductivity type. If the first conductivity type is n-type, then the second conductivity type is p-type, and vice versa. In one embodiment, the first conductivity type is n-type, and the second conductivity type is p-type. Each second conductivity type semiconductor layer 14 may comprise a crystalline (e.g., single crystalline or polycrystalline) GaN, InGaN, AlGaN and/or AlInGaN layer. Thus, the active layer 13 is located between the first conductivity type semiconductor layer 12, and the second conductivity type semiconductor layer 14.

A contact-level material layer 15 may be formed over the second conductivity type semiconductor layer 14. The contact-level material layer 15 may include at least one electrically conductive layer which functions as an electrode (e.g., p-type side electrode). The contact-level material layer 15 may include a layer stack including, from bottom to top, a transparent conductive oxide layer, a reflector layer and/or a bonding pad material layer. The transparent conductive oxide layer may include a transparent conductive oxide material such as indium tin oxide or aluminum doped zinc oxide. The reflector layer may include gold, silver and/or aluminum. The bonding pad material layer may include a metallic material that can function as a bonding pad, such as gold, copper, nickel, titanium, titanium nitride, tungsten, tungsten nitride, another metal having a higher melting point than a solder material to be subsequently employed, alloys thereof, and/or layer stacks thereof.

The stack of second conductivity type semiconductor layer 14, active layer 13, and optionally the first conductivity type semiconductor layer 12 within each LED 10A, 10B, 10C may be patterned employing various patterning methods to form grooves 19 between adjacent LEDs 10A, 10B, 10C. A dielectric matrix layer 16 can be formed between the first LEDs 10A, 10B, 10C. The grooves 19 define the area of each LED 10A, 10B, 10C. Specifically, each continuous set of patterned material layers overlying the growth substrate 8 and laterally enclosed by a set of grooves 19 may constitute the LED 10A, 10B, 10C. In one embodiment, the grooves 19 can be formed in a lattice pattern to provide an array of LEDS, which may be a periodic array of the LEDs. The LEDs 10A, 10B, 10C can emit light at a first peak wavelength, such as a blue light having the first peak wavelength in the blue spectral range.

While FIG. 2 illustrates a specific embodiment of an LED coupon 1 including LEDs 10A, 10B, 10C, embodiments of the present disclosure can be utilized employing any configuration for LEDs 10A, 10B, 10C provided that a structure for attaching a bonding material portion may be provided on a side of the LED 10A, 10B, 10C that faces away from the growth substrate 8.

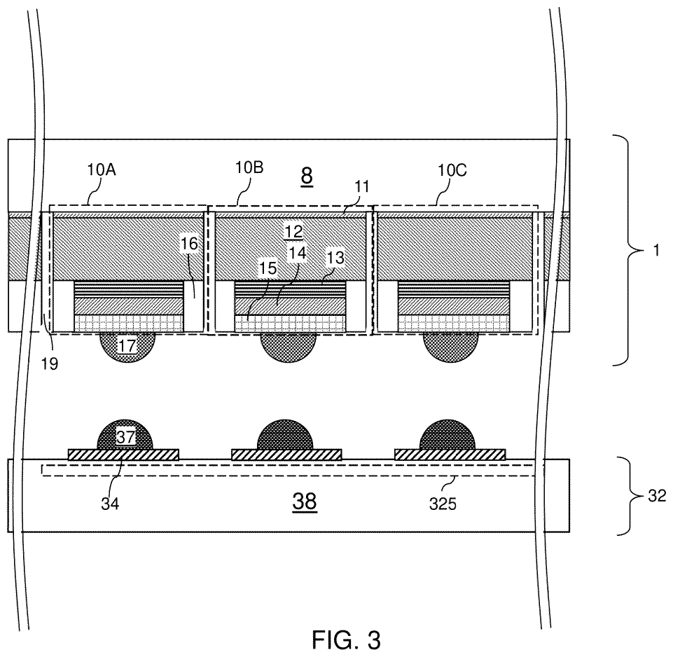

FIG. 3 illustrates an arrangement of the LED coupon 1 in preparation of transferring the LEDs 10A, 10B, 10C from the LED coupon 1 to a backplane 32, according to some embodiments. As illustrated in FIG. 3, a diode-side bonding material portion 17 may be formed on the contact-level material layer 15 in each of the LEDs 10A, 10B, 10C. In one embodiment, the diode-side bonding material portions 17 can be solder material portions such as pure tin or an alloy of tin and indium.

The backplane 32 may be a single large panel version of substrate 38 or several substrates 38 arranged to fit in the space of a large panel, and a metal interconnect layer 325 formed on a front side surface of the substrate 38. In one embodiment, the substrate 38 can include a plastic (e.g., polymer) substrate, a glass substrate or a silicon substrate. The backplane 32 may also have a large size (e.g., Gen 8 or greater). In one embodiment, the metal interconnect layer 325 can include a plurality of metal interconnect structures located on the surface of the substrate 38 and/or embedded in at least one insulating material and providing electrical connections between the LEDs to be bonded onto the backplane 32 and input/output pins of the backplane 32.

Bonding pads 34 may be formed on a surface of the backplane 32 (e.g., a surface of substrate 38) that overlies the metal interconnect layer 325. In one embodiment, the bonding pads 34 can be arranged as a two-dimensional periodic array or as a one-dimensional periodic array. The bonding pads 34 may include a bonding pad material such as gold, copper, nickel, titanium, titanium nitride, tungsten, tungsten nitride, another metal having a higher melting point than a solder material to be subsequently employed, alloys thereof, and/or layer stacks thereof.

A backplane-side bonding material portion 37 may be formed on the bonding pads 34. In one embodiment, the backplane-side bonding material portions 37 can be solder material portions such as pure tin or alloy of tin and indium. The LED coupon 1 and the backplane 32 may be aligned such that a pair of a diode-side bonding material portion 17 and a backplane-side bonding material portion 37 face each other at every lattice point of the periodic array of the bonding pads 34.

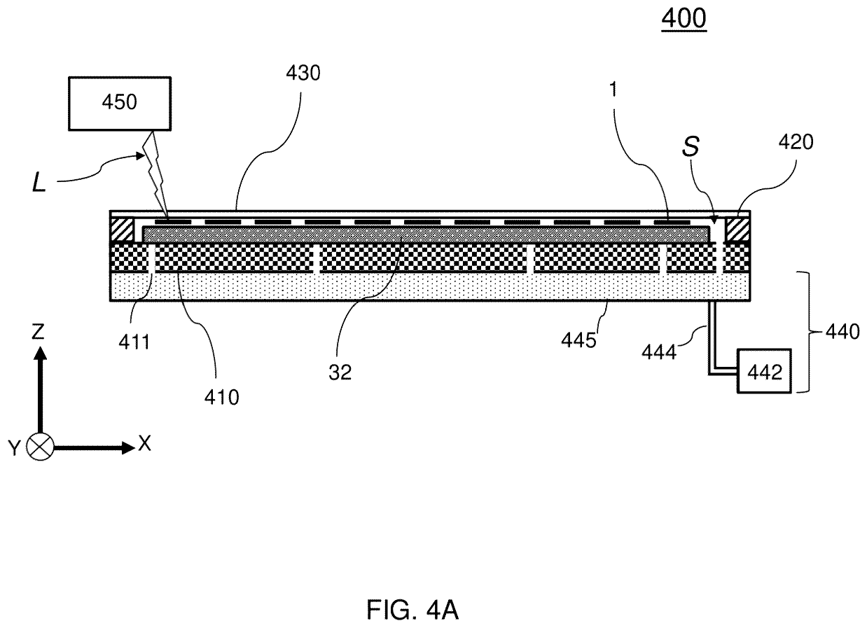

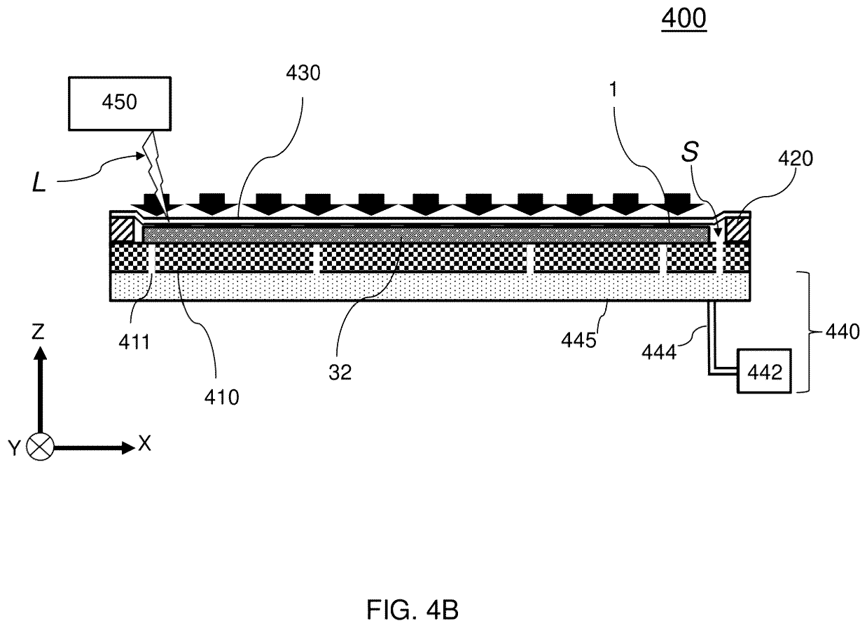

FIG. 4A illustrates an apparatus 400 that may be used to transfer the LEDs 10A, 10B, 10C from the LED coupons 1 to the backplane 32, according to some embodiments.

Hereinafter, the method may be described specifically with respect to LED 10A, however, the LEDs 10B and 10C may be sequentially transferred to the same backplane 32 according to the same method.

The apparatus 400 may include a backing board 410 for supporting a backplane 32, a sealing member 420 formed on the backing board 410 around a periphery of the backplane 32, a transparent panel 430 placed on the sealing member 420 such that a space S is formed between the backing board 410 and the transparent panel 430, and a vacuum source 440 for drawing a vacuum on the space S.

The apparatus 400 may also include a laser radiation source (i.e., a laser) 450 that directs a laser radiation L through the transparent panel 430 to irradiate the LED coupon 1 formed on the backplane 32 in the space S. In one embodiment, the laser radiation source 450 may emit laser radiation L that irradiates buffer layer 11 of the LED 10A to perform a partial laser lift off process of the LED 10A.

A process of transferring LEDs to the backplane 32 may be performed, for example, at room temperature, and may begin by placing the backplane 32 on a backing board 410 (e.g., non-compliant, rigid backing board) that is in a vacuum laminator 445, and then placing a plurality of LED coupons 1 on the backplane 32. The LED coupons 1 may include, for example, micro-LED coupons that each include a substrate (e.g., growth substrate) and a plurality of micro-LEDs that are formed on the substrate and are to be transferred from the substrate to the backplane 32. The micro-LEDs may have a size, for example, that is much less than about 100 microns, and may be as small as 1 to 20 microns, for example 2 to 10 microns. However, larger LEDs or monolithic arrays of LEDs may also be transferred.

The plurality of LED coupons 1 may be arranged on the backplane 32 in an array so that a diode-side bonding material portion 17 formed on the LEDs 10A, 10B, 10C is aligned with a backplane-side bonding material portion 37 on the bonding pads 34 that are arranged in an array on the backplane 32 as shown for example in FIG. 3. In particular, the LED coupons 1 may be “tiled” on the backplane 32 so as to cover substantially the entire backplane 32. The alignment of the LED coupons 1 may be performed, for example, by an optical sensor (not shown) which determines a precise location of the LED coupon 1 and robotic arm (not shown) which positions the LED coupon 1 into the precise location.

The transparent panel 430 may then be placed over the plurality of LED coupons 1 and over the sealing member 420 such that a space S is formed between the backing board 410 and the transparent panel 430. The vacuum source 440 may then draw a vacuum on the space S, and the vacuum drawn on the space may pull the transparent panel 430 toward the backplane 32 causing the transparent panel 430 to press the LED coupon 1 toward the backplane 32. In particular, a pressure with which the transparent panel presses on the plurality of LED coupons may be substantially uniform over the plurality of LED coupons.

In some embodiments the backing board 410 may include a rigid backing board that is made, for example, of metal or rigid polymer material. The backing board 410 may include a vacuum laminator backing board and may include one or more slits 411 (e.g., through holes, channels, etc.) for allowing the vacuum source 440 to access the space S and allow the vacuum source 440 to draw a vacuum in the space S through the slits 411. Alternatively, the vacuum may be drawn through or adjacent to the lateral sides of the backing board 410 in addition to or instead of through the slits 411. The backing board 410 must also have a size (e.g., area) great enough to accommodate a backplane 32 of a large size (e.g., Gen 8 or greater), and to accommodate the sealing member 420 that may be formed around a periphery of the backplane 32.

The sealing member 420 may be a perimeter shim frame that may eliminate edge-effects and provide a good seal with the transparent panel 430. In some embodiments, the sealing member 420 may include an O-ring type or gasket type of sealing member that may be configured in a rectangular shape that approximates a shape of the backplane 32. The sealing member 420 may be formed continuously around the periphery of the backplane 32 so that a gap (e.g., in the X-direction of FIG. 4A) between the sealing member 420 and the periphery of the backplane 32 is no more than about two centimeters. The sealing member 420 may be formed, for example, of a polymer material, such as polyurethane, silicone, neoprene, nitrile rubber, fluorocarbon, polytetrafluoroethylene (PTFE), or ethylene propylene diene monomer (EPDM) rubber. A thickness (e.g., in the Z-direction of FIG. 4A) of the sealing member 420 should be substantially the same as a sum of thicknesses of the backplane 32 and the LED coupon 1. If the thickness of the sealing member 420 is too small, then the transparent panel 430 may rest on the LED coupons 1 and not contact the sealing member 420 so that no seal can be formed around the space S. However, if the thickness of the sealing member 430 is too great, then the distance between the transparent panel 430 and backplane 32 may be too great to allow the transparent panel 430 to push the LED coupons 1 toward the backplane 32 under vacuum. Thus, where a sum of thicknesses of the backplane and LED coupon is given as Tb, a thickness Ts of the sealing member 420 may be in a range from 0.9Tb ≤Ts ≤1.1Tb.

The transparent panel 430 may be a compliant (e.g., pliable or bendable) transparent panel which may be large enough (e.g., have an area large enough) to cover the sealing member 420 around the entire periphery of the backplane 32. In other words, the transparent panel 430 may have lower stiffness (i.e., lower rigidity and a lower Young's modulus) than the backing board 410. The transparent panel 430 may also be sufficiently transparent so as not to interfere with the laser radiation L that is being directed through the transparent panel 430 at the LED coupons 1 in the space S. In one embodiment the transparent panel 430 may have a thickness of not greater than a few millimeters (e.g., less than about 5 millimeters, such as 0.1 to 2 mm, for example 0.5 to 1 mm). If the thickness is too great, then the focal point of the laser radiation from the source 450 may be too far from the work surface on the LED coupons 1 during the subsequent laser irradiation steps. The transparent panel 430 may be formed of glass, such as borosilicate glass, although other glass may be used, as long as they are transparent to the laser radiation emitted by the laser radiation source 450.

The vacuum source 440 may include the vacuum laminator 445, a vacuum pump 442 for drawing the vacuum, and piping 444 that connects the vacuum pump 442 to one or more vacuum ports on the vacuum laminator 445. The vacuum pump 442 may be capable of drawing a sufficient vacuum in the space S, so that a pressure with which the transparent panel 430 presses the LED coupon 1 can be easily and very accurately controlled to any pressure ranging all the way up to atmospheric pressure, 14.7 psi, and is applied substantially uniformly over an entirety of the transparent panel 430.

The laser radiation source 450 may include one or more types of lasers for generating laser radiation L at different wavelengths and powers. The laser radiation source 450 may be configured to perform in situ laser lift-off (LLO) and laser scanning (LS) raster (e.g., in the Y-direction of FIG. 4A) while the backing board 410 is indexed in the perpendicular direction (e.g., in the X-direction of FIG. 4A). In particular, the laser radiation source 450 may generate a detachment laser beam LD for detaching the LED 10 from the LED coupon 1 in a partial laser lift-off process. The detachment laser beam LD may have an ultraviolet wavelength or a wavelength in a visible light range. In some embodiments, the laser radiation source 450 may include an excimer (UV) laser with a wavelength of 248 nm or 193 nm for generating the detachment laser beam LD. The laser radiation source 450 may also generate a laser beam LB (e.g., infrared laser beam) during a bonding laser irradiation process. In some embodiments, the laser radiation source 450 may include a CO₂ laser for generating laser beam LB (e.g., infrared laser beam) having a wavelength of 9.4 microns or 10.6 microns. Thus, the laser radiation source 450 may include two or more different lasers.

FIG. 4B illustrates a side view of the apparatus 400 after the pulling of a vacuum on the space S by the vacuum source 440, according to some embodiments. As illustrated in FIG. 4B, the transparent panel 430 may be pliable so that it flexes downward (e.g., in the Z-direction in FIG. 4B) under the vacuum drawn by the vacuum source 440 in space S that is sealed by the sealing member 420. The amount of downward pressure applied by the transparent panel 430 on the LED coupon 1 may be regulated by regulating the amount of vacuum drawn by the vacuum source 440, and therefore, may be regulated by an amount of current supplied to the vacuum pump 442. That is, the downward pressure may be increased by increasing a vacuum drawn by the vacuum source 440, and may be decreased by decreasing a vacuum drawn by the vacuum source 440. In some embodiments, a downward pressure applied by the transparent panel 430 on the LED coupon 1 may be 10 to 15 psi, and may be applied substantially uniformly over an entirety of the transparent panel 430.

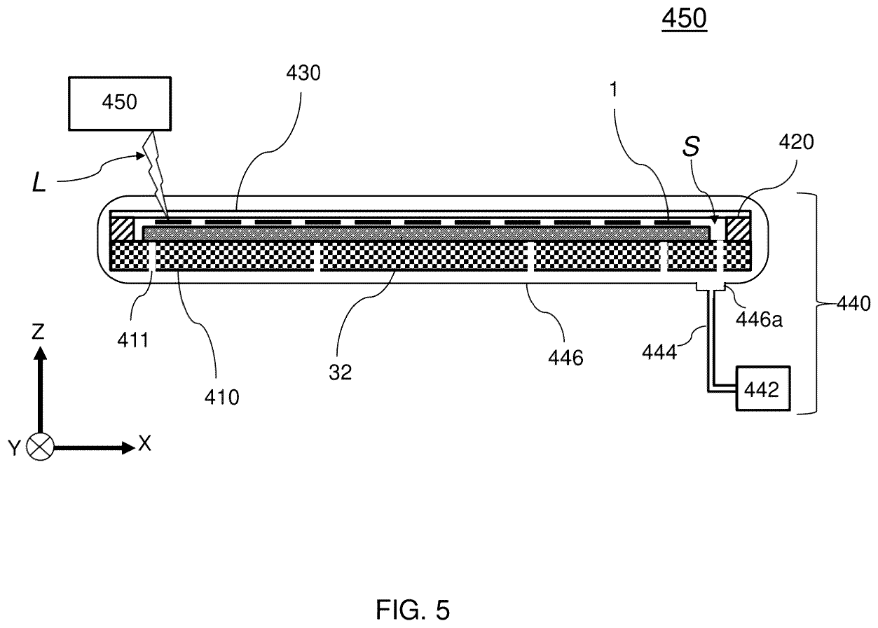

FIG. 5 illustrates a side view of an apparatus 450 for transferring LEDs according to some embodiments. As illustrated in FIG. 5, the apparatus 450 may include the features of apparatus 400 in FIGS. 4A-4B, except that the vacuum source 440 may be different. In the apparatus 450, the vacuum source 440 may include a vacuum bag 446 that may be formed over the backing board 410, sealing member 420 and transparent panel 430. The vacuum bag 446 may be made of plastic or another material that is transparent to and unaffected by the laser radiation L emitted from the laser radiation source 450. The vacuum bag 446 may also include one or more ports 446a to which the vacuum piping 444 may be connected. In operation, the vacuum source 440 may draw a vacuum on the space S by drawing a vacuum on the vacuum bag 446 with substantially the same result as provided by apparatus 400 that is illustrated in FIG. 4B. That is, the vacuum causes a downward pressure to be applied by the transparent panel 430 on the LED coupon 1, and that downward pressure may be 10 to 15 psi, and applied substantially uniformly over an entirety of the transparent panel 430.

In some embodiments, the apparatus 400 and the apparatus 450 may provide a uniform clamping pressure over very large area panels, such as Gen 8 size and above (e.g., 20 inches diagonal or larger), for the purpose of micro-LED mass transfer, and may work equally well with multi-transfer coupon design (e.g., different color LED coupons). In particular, the apparatus 400 and the apparatus 450 may reduce the height distribution difference and shifting the neutral stress point upward, such that gap and stress distributions remain in an acceptable range across an entire micro-LED array, and from one process step to the next process step. Therefore, the inherent micron size range waviness in the backplane and/or the LED coupons (e.g., due to surface roughness or warpage) may be reduced or eliminated by the uniform pressure applied by the apparatus across the entire backplane area. This improves the bonding quality and accuracy and improves display device yield because non-uniform coupon height with respect to the backplane hinders mass LED transfer and decreases display device yield.

In apparatus 400, a method of transferring LEDs may begin with placing the backplane 32 (e.g., display backplane) on a backing board 410 (e.g., rigid backing board) in a vacuum laminator 445, whereas in apparatus 450, the method may begin with placing the backplane 32 (e.g., display backplane) on a backing board 410 (e.g., rigid backing board) in a vacuum bag 446. The LED coupons may be placed (e.g., tiled) on the backplane 32 (e.g., display panel, TV panel, etc.) until they cover the entire backplane 32. The sealing member 420 (e.g., shim frame) may be placed around the perimeter of the backplane 32 to eliminate edge-effects and provide a good seal. The transparent panel 430 (e.g., cover glass) may then be placed on top of the LED coupons 1 so as to form the space S that is sealed by the sealing member 420. The vacuum source 440 may then be used to draw a vacuum in the space S until a desired level of vacuum (e.g., pressure) is reached. These process steps may be repeated for LED coupons 1 containing different color LEDs.

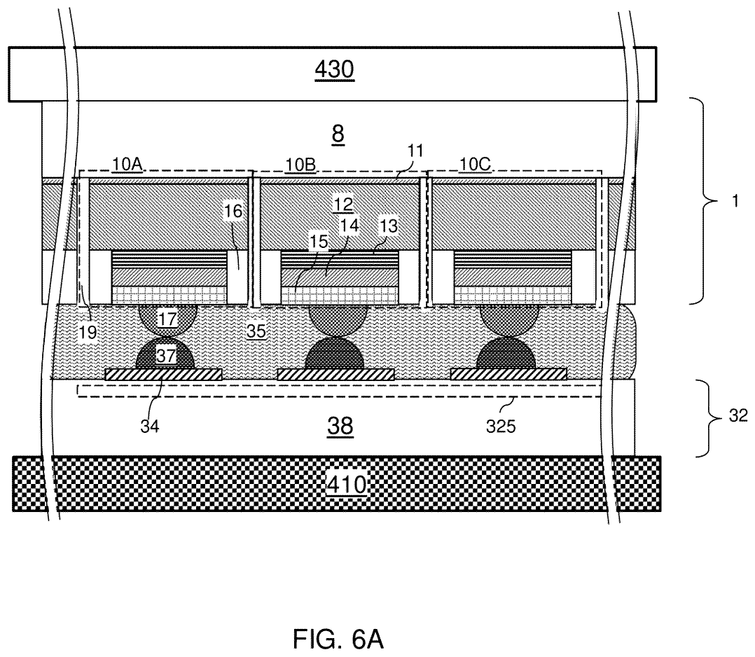

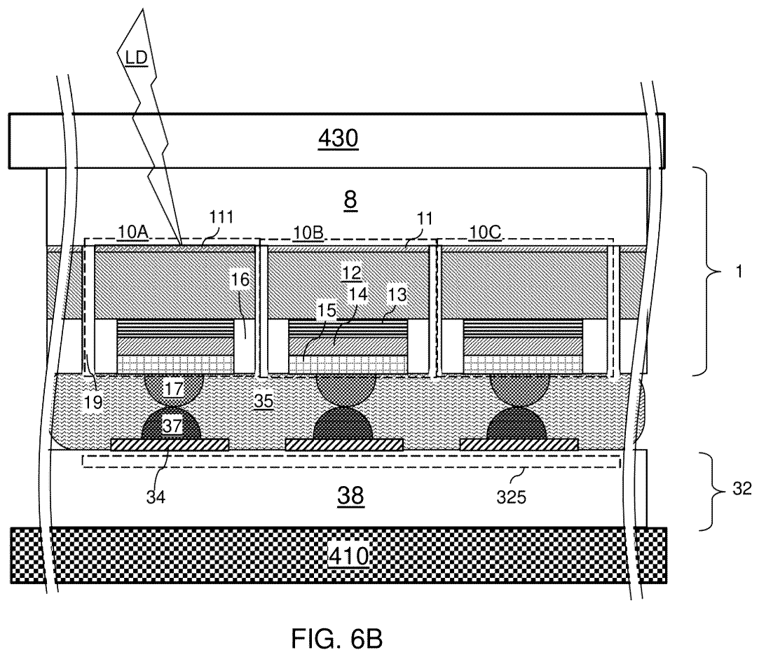

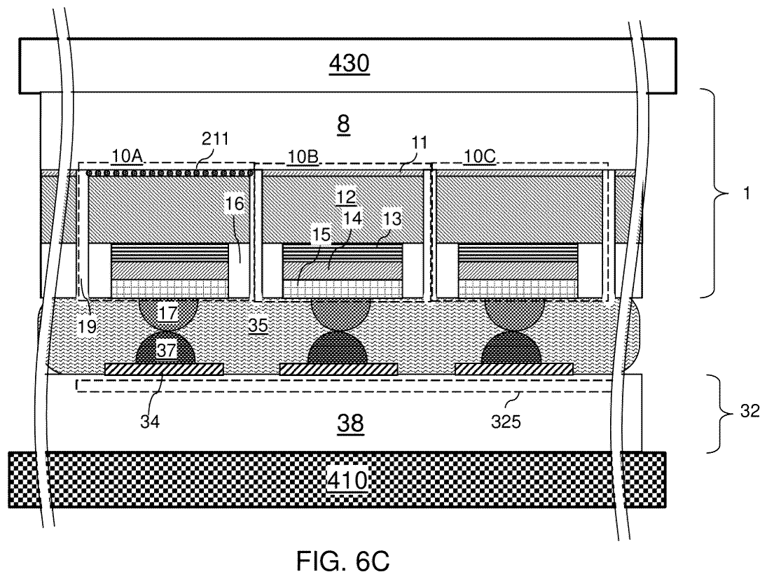

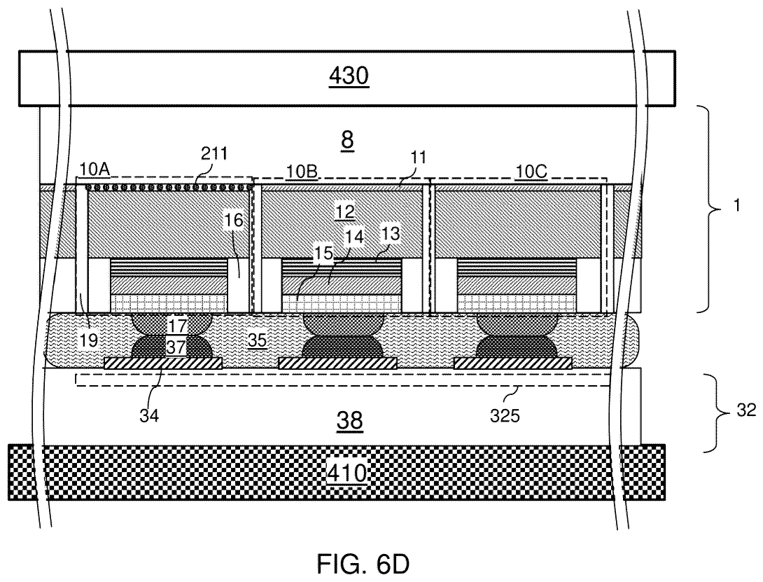

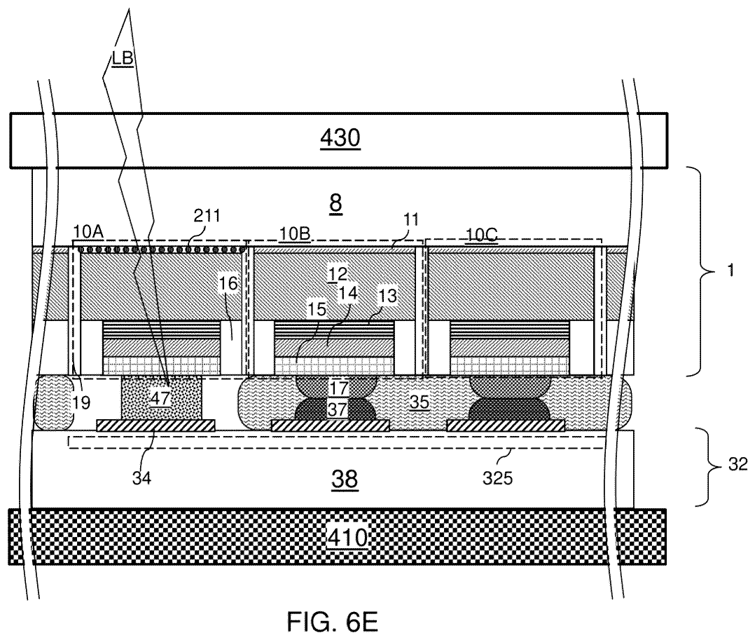

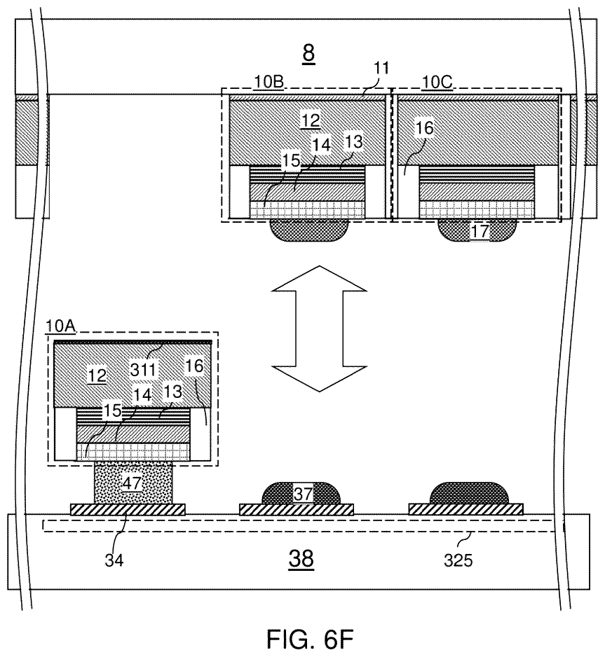

Referring again to the drawings, FIGS. 6A-6F illustrate a method of transferring the LED 10A from LED coupon 1 to the backplane 32, according to some embodiments. As noted above, the same method may also be used to transfer LEDs 10B and 10C to the backplane 32. The method may be implemented by using either apparatus 400 or apparatus 450 that are described above. As illustrated in FIG. 6A, the backplane 32 may be placed on a backing board 410, the LED coupon 1 may be placed on the backplane 32, and the transparent panel 430 may be placed on the LED coupon 1, according to some embodiments. The LEDs 10A, 10B, 10C of LED coupon 1 may be brought into contact with the backplane 32 such that each facing pair of a diode-side bonding material portion 17 and a backplane-side bonding material portion 37 contact each other. Each of the diode-side bonding material portion 17 can have an areal overlap with a respective underlying backplane-side bonding material portion 37. In one embodiment, the area of the overlap may be at least 70%, such as more than 80% and/or more than 90%, of the area of the diode-side bonding material portion 17. In one embodiment, the geometrical center of each diode-side bonding material portion 17 can overlie a geometrical center of an underlying backplane-side bonding material portion 37.

Generally, at least one bonding material portion (17, 37) can be disposed between each vertically neighboring pair of a respective one of the bonding pads 34 and a respective one of the LEDs 10A, 10B, 10C. In one embodiment, a pair of a diode-side bonding material portion 17 and a backplane-side bonding material portion 37 can be provided between each vertically neighboring pair of a respective one of the bonding pads 34 and a respective one of the LEDs 10A, 10B, 10C. In one embodiment, the diode-side bonding material portions 17 may be omitted. In another embodiment, the backplane-side bonding material portions 37 may be omitted.

In one embodiment, a solder flux 35 may be applied between the backplane 32 and the LEDs 10A, 10B, 10C such that the solder flux 35 laterally surrounds each bonding material portion (17, 37). The solder flux 35 may be any suitable liquid flux which reacts with tin oxide to leave metallic tin bonding material portions (17, 37).

With the LED coupon 1 formed on the backplane 32 as in FIG. 6A, the vacuum source 440 may be engaged to cause the transparent panel 430 to apply a first pressure (e.g., first amount of downward pressure (e.g., downward force)) to the LED coupon 1 so as to hold the LED coupon 1 in place on the backplane 32 without lateral slippage. In particular, the backplane 32 and the LED coupon 1 can be held in place while a downward force is applied by the transparent panel 430 to the LED coupon 1, the bonding material portions (17, 37) and the backplane 32 along the vertical direction. The magnitude of the downward force can be selected such that the bonding material portions (17, 37) are not deformed in a significant manner, i.e., the bonding material portions (17, 37) maintain the shapes as provided prior to clamping, and without bonding the respective bonding material portions 17 and 37 to each other. In an illustrative example, if 2,000,000 pairs of a diode-side bonding material portion 17 and a backplane-side bonding material portion 37 are present between a 4 square meter sized backplane 32 and the tiled LED coupons 1, then the magnitude of the downward force applied by the transparent panel 430 may be in a range from 250 N to 400 N or about 0.1 mN to 0.2 mN per LED.

Referring to FIG. 6B, a sequential laser irradiation process may be performed to irradiate buffer layer 11 of the LED 10A that is to be transferred to the backplane 32 with a detachment laser beam LD that is emitted from the laser radiation source 450. The detachment laser beam LD may perform a partial laser liftoff process used to partially lift off the LED 10A, and is herein referred to as a detachment laser irradiation process. Each buffer layer 11 of the LEDs 10A, 10B, 10C may be sequentially irradiated with the detachment laser beam LD one by one. The lateral dimension (such as a diameter) of the detachment laser beam LD can be about the same as the lateral dimension of the LEDs 10A, 10B, 10C. Thus, each buffer layer 11 can be individually irradiated without causing significant compositional changes in neighboring buffer layers 11.

The detachment laser beam LD can have an ultraviolet wavelength or a wavelength in a visible light range, and may be absorbed by the gallium and nitrogen containing III-V compound semiconductor material of the irradiated buffer layer 11. Without wishing to be bound by a particular theory, it is believed that irradiation of the detachment laser beam LD onto a buffer layer 11 evaporates nitrogen atoms without evaporating, or with minimal evaporation of, gallium atoms. The irradiation thus reduces the atomic percentage of nitrogen in a remaining material. The LED coupon 1 and the backplane 32 can be held in place by the pressure applied by the transparent panel 430 on the LED coupon 1 during and after this step.

In one embodiment, and without being bound by a particular theory, it is believed that the irradiated buffer layer 11 of LED 10A may be converted into gallium-rich drops 111. The gallium-rich drops 111 may consist of pure liquid gallium-rich drops or may include an alloy of gallium and nitrogen containing gallium at an atomic concentration greater than 55%, such as 60% to 99%.

As shown in FIG. 6C, the liquid gallium-rich drops 111 may solidify into solid gallium-rich material portions (e.g., pure gallium or gallium rich alloy particles or regions) 211 after the irradiation if the LED coupon 1 temperature is maintained below the melting temperature of gallium (e.g., 29.76° C.) or its alloy. In one embodiment, the gallium-rich material portions 211 can include gallium atoms at an atomic concentration greater than 55%, such as 60% to 100%. The gallium-rich material portions 211 can have an average thickness in a range from 5 nm to 100 nm, such as from 10 nm to 50 nm, although lesser and greater thicknesses can also be employed. The gallium-rich material portion 211 may comprise a continuous material layer, or may comprise a cluster of ball-shaped material portions. The buffer layers 11 of the LEDs 10B, 10C on the LED coupon 1 that are not irradiated with the laser beam LD remain as buffer layers 11, such as gallium nitride buffer layers having about 50 atomic percent gallium and thus having a higher melting point than the gallium-rich material portions 211.

Since a backplane-side bonding material portion 37 and a diode-side bonding material portion 17 within each adjoining pair merely contact each other during the laser irradiation and are not bonded to each other, the mechanical shock from the laser irradiation is not transmitted to the backplane 32 that can include a relatively fragile polymer. Thus, the partial laser liftoff described above with respect to FIGS. 6B and 6C which forms the gallium-rich material portions 211 may cause little or no damage to the backplane 32 and to the electrically conductive elements (34, 325) on the backplane 32. Further, the partial laser liftoff process prevents damage to re-solidified bonding material portions in subsequent processing steps because the bonding reflow happens after the partial laser liftoff.

Referring to FIG. 6D, the backplane 32 and the LED coupon 1 can be pressed against each other with a greater force to induce deformation of the bonding material portions (17, 37) (i.e., to coin the bonding material portions to smooth out any rough bonding surfaces). Thus, each mating pair of a respective diode-side bonding material portion 17 and a respective backplane-side bonding material portion 37 can be pressed against each other at a second pressure that is greater than the first pressure after conversion of the buffer layer 11 of LED 10A into the gallium-rich material portion 211. As illustrated in FIG. 6D, the second pressure may be sufficient to cause deformation of the diode-side bonding material portions 17 and the backplane-side bonding material portions 37. In an illustrative example, if 100,000 pairs of a diode-side bonding material portion 17 and a backplane-side bonding material portion 37 are present between the backplane 32 and the LED coupon 1, then a magnitude of the pressure applied by the transparent panel 430 may be in a range from 500 N to 1,000 N.

Referring to FIG. 6E, a localized laser irradiation process can be performed to induce reflow and bonding of the mating pair of a diode-side bonding material portion 17 and a backplane-side bonding material portion 37 that underlies the LED 10A. The laser irradiation induces bonding of the LED 10A to the backplane 32, and is herein referred to as a bonding laser irradiation process. The laser beam LB employed during the bonding laser irradiation process may have a photon energy that is less than the band gap of the III-V compound semiconductor materials (e.g., gallium and nitrogen containing materials) in the LED 10A and thus may pass through the LED 10A. For example, the laser beam LB employed during the bonding laser irradiation process may be an infrared laser beam such as a carbon dioxide laser beam having a wavelength of 9.4 microns or 10.6 microns.

The irradiated pair of a diode-side bonding material portion 17 and a backplane-side bonding material portion 37 connected to LED 10A may be heated to a reflow temperature at which the bonding materials (which may be solder materials) of the pair of the diode-side bonding material portion 17 and the backplane-side bonding material portion 37 reflow. Upon termination of the irradiation of the laser beam LB onto the mating pair of a diode-side bonding material portion 17 and a backplane-side bonding material portion 37, the reflowed material re-solidifies to provide a re-solidified bonding material portion 47. The re-solidified bonding material portion 47 is thus bonded to a bonding pad 34 and contact-level material layers 15 of the LED 10A.

Thus, the LED 10A can be bonded to a respective underlying one of the bonding pads 34 by localized laser irradiation onto a respective underlying set of at least one bonding material portion (17, 37), which are reflowed and re-solidify to form a re-solidified bonding material portion 47. During the localized laser irradiation for transferring LED 10A, the mating pair of the diode-side bonding material portions 17 and the backplane-side bonding material portions 37 for LEDs 10B, 10C can be pressed against each other at the second pressure. Thus, the LED 10A can be bonded to the backplane 32, and the LEDs 10B, 10C on the LED coupon 1 can remain not bonded to the backplane 32. The gallium-rich material portions 211 provide weak adhesion force between the growth substrate 8 and a first conductivity type semiconductor layer 12. Since the LED 10A is held in place by the gallium-rich material portions 211, a lower power laser beam LB may be used than in prior art bonding processes. This further reduces damage to the backplane 32. The solder flux 35 may be evaporated during irradiation with laser beam LB or may be poured out after this step.

Referring to FIG. 6F, the vacuum source 440 may cease to draw a vacuum on the space S between the backplane 32 and the LED coupon 1, so that the transparent panel 430 stops applying a downward pressure on the LED coupon 1. The backplane 32 may then be heated to a temperature above the melting temperature of the gallium-rich material portions 211 but below the melting temperature of the amorphous buffer layer 11 (e.g., below the melting temperature of gallium nitride). For example, if the gallium-rich material portions 211 comprise pure gallium, then the temperature may be raised to at least 30 degrees Celsius (e.g., 35 to 50 degrees Celsius) to melt to the gallium-rich material portions 211 into gallium-rich drops 111. This may allow the LED 10A to be separated from the growth substrate 8 with or without applying a mechanical force, while the LEDs 10B, 10C are unaffected and remain fixed to the growth substrate 8. Optionally, a gallium-rich material portion 311 (such as re-solidified gallium-rich drops 111 or remnants of portion 211) can be located on a surface of a first conductivity type semiconductor layer 12.

The same method may be sequentially used to transfer LEDs 10B and 10C to the backplane 32. Specifically, the vacuum is released and remaining portions of the LED coupons 1 containing first color LEDs 10A are removed from the apparatus 400 or 450 (i.e., moved away from the backplane 32 after the transparent panel 430 is lifted up) while the bonded LEDs 10A remain bonded to the backplane. Then different LED coupons 1 containing different color LEDs 10B are placed on the backplane 32. The vacuum is drawn again and the process steps of FIGS. 6A to 6F is repeated for LEDs 10B. The same steps are then repeated for LEDs 10C.

Further embodiments include systems and methods for wafer-level laser transfer and bonding of LEDs from a substrate to a backplane with highly concentrated and highly uniform pressure applied to the substrate 8 (e.g., a semiconductor or sapphire wafer or large panel substrate), without having to dice the substrate 8 into separate coupons 1 before laser transfer. In this regard transfer of micro LEDs from a sapphire substrate to a backplane substrate in digital display applications should have good electrical contact, accurate x-y placement, uniform x-y-z placement, good adhesion, and high yields due to the large quantity of devices to be transferred. Bonds between LEDs and the backplane may be achieved with a eutectic solder bond, which may require the material to be subjected to high reflow temperatures. However, due to CTE mismatch between the substrate, backplane and bonding materials, it may not be possible to reliably maintain x-y placement accuracy using thermal (i.e., furnace) processing. Laser solder reflow, described above, allows localized thermal processing, maintaining the overall substrate stack under room temperature. On the other hand, to maintain uniform, high pressure on the substrate stack (i.e., substrate with LEDs) while also allowing an optical path for the laser beam to reach the work area may also be challenging. Embodiment systems and methods solve this problem and extend the applicability of laser-based, room temperature mass transfer to any size substrate.

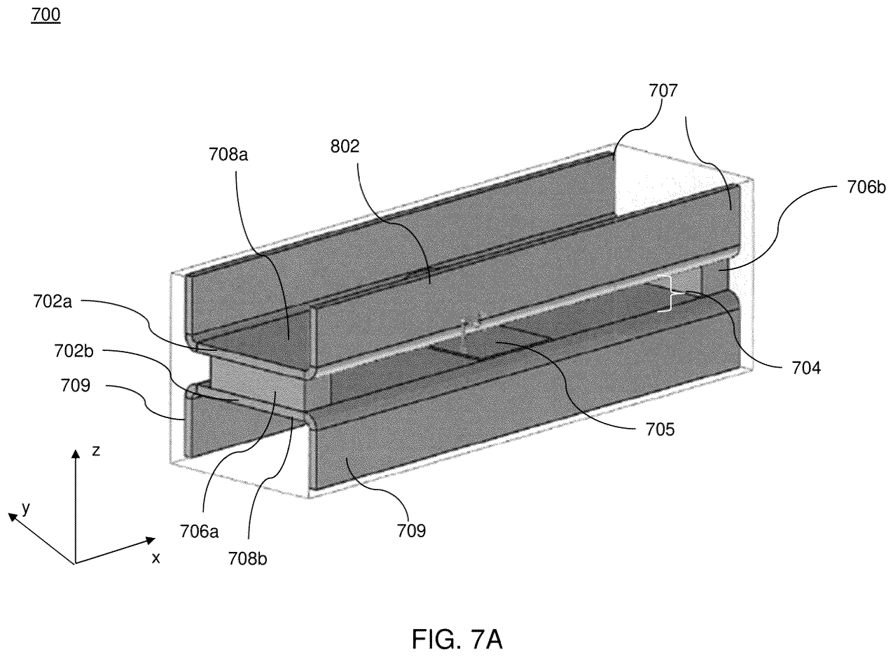

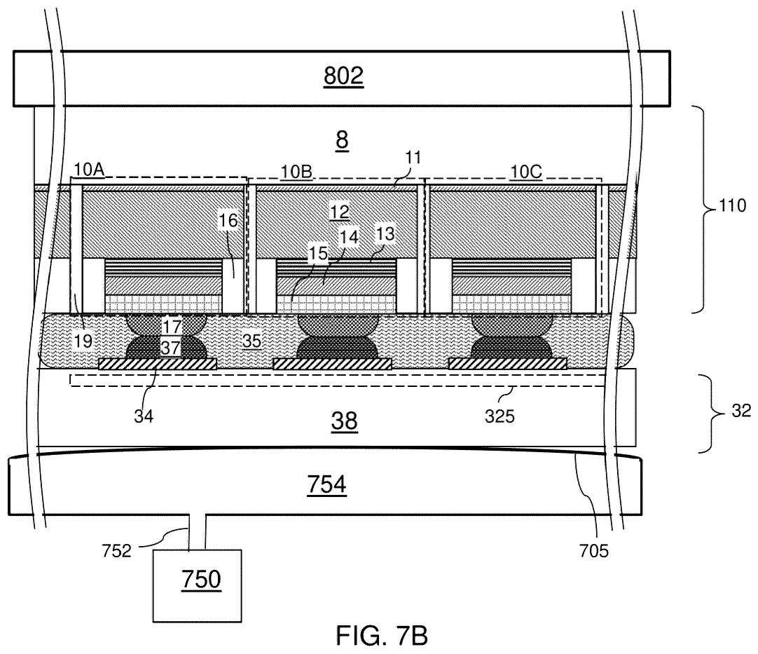

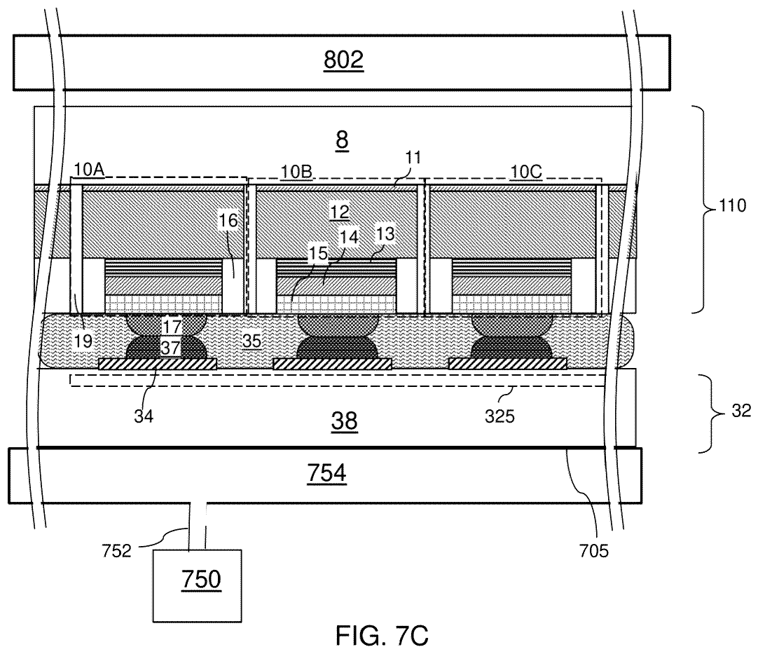

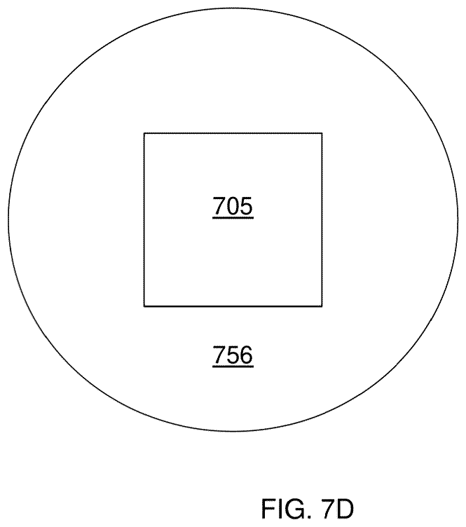

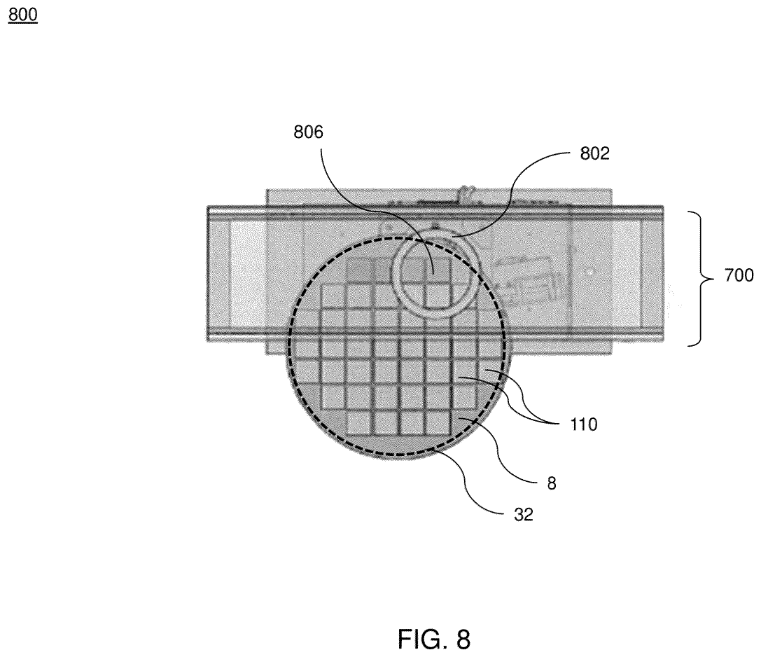

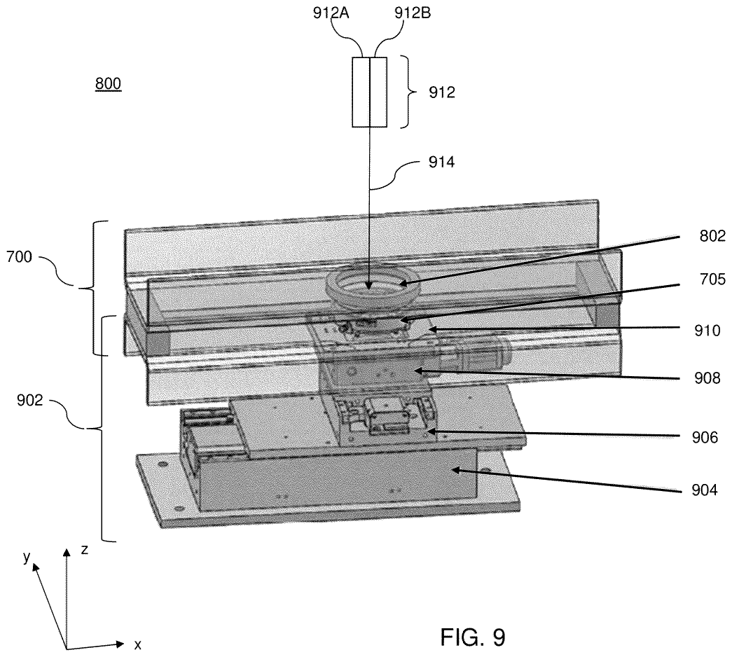

FIG. 7A is a three dimensional perspective view of a component 700 of an apparatus for transferring LEDs, according to some embodiments. The component 700 may be configured as a substrate housing having of a rigid, lightweight channel structure configured to suspend an optically transparent mechanical stop (i.e., an optic flat) 802 above a work surface, as described in greater detail with reference to FIGS. 8 and 9, below. As shown in FIG. 7A, the component 700 may include a rigid clamp frame structure including a first structural member 702a supported above a second structural member 702b thereby forming an open channel 704 between them.

In one embodiment, the first structural member 702a may comprise a first channel structure having a first horizontal plate (i.e., a first planar surface) 708a supporting the optically transparent mechanical stop 802 therein, and at least one rigid stiffner rib, such as two stiffner ribs 707 extending upwards from the elongated edges of the first horizontal plate 708a to provide increased stiffness to the first structural member 702a.

In one embodiment, the second structural member 702b may comprise a second channel structure base having a second horizontal plate (i.e., a second planar surface) 708a supporting a movable member 705 therein, and at least one rigid stiffner rib, such as two stiffner ribs 709 extending downward from the elongated edges of the second horizontal plate 708b to provide increased stiffness to the second structural member 702b.

The first structural member 702a may be connected to the second structural member 702b by its ends, so pressure can be applied at the center of a large substrate by a movable member 705 in the work surface in the second structural member 702b. The connection may comprise a first base member 706a and a second base member 706b that rigidly hold the first structural member 702a and the second structural member 702b at respective first ends and second ends of the first structural member 702a and the second structural member 702b.

The movable member 705 may be supported by the second structural member 702b. The rigid structure may be configured to receive a substrate 8 (e.g., see FIGS. 7B and 8) in the open channel 704 and to clamp the substrate 8 containing a plurality of LED dies 110 to a backplane 32 (shown in dashed lines in FIG. 8) located under the substrate 8 by generating a pressure on the movable member 705 such that the movable member 705 presses on the backplane 32 from a first side of the backplane 32 (e.g., the bottom of the backplane) to thereby generate a first force on the first side of the backplane 32 that presses a second side of the backplane 32 (e.g., the top of the backplane containing the bonding structures 37) into one or more of the LED dies 110 on the substrate 8, and which causes the backside (i.e., bottom) of the substrate 8 in to be pressed against the optically transparent mechanical stop 802, as shown in FIG. 7B. The movable member 705 may be sized to press one or more than one of the LED dies 110 against the optically transparent mechanical stop 802. In this embodiment, the backplane 32 may comprise a CMOS backplane which includes a semiconductor (e.g., silicon) wafer supporting various driver circuitry, such as a transistors in a CMOS configuration and bonding pads or other bonding structures for bonding the LED die 110 to the backplane 32.

As shown in FIG. 7B the apparatus may further include a source of a compressed gas 750 (e.g., an air tank or an inert gas, such as nitrogen, tank) and a chamber 754 configured to receive the compressed gas via piping 752. The movable member 705 may be a flexible membrane (e.g., a diaphragm) located on a top wall of the chamber 754. The chamber 754 may comprise an air or nitrogen bladder, which is shown in its inflated state in FIG. 7B. The flexible membrane is configured to expand upwards in response to the pressure generated by the compressed gas when the compressed gas is introduced from the source 750 through the piping 752 into the chamber 754. The upward expansion of the flexible membrane causes the flexible membrane to press up against the bottom of the backplane 32. In this way, the pressure causes the substrate 8 to be pressed upwards and become rigidly clamped to the optically transparent mechanical stop 802. The optically transparent mechanical stop 802 may comprise an optic flat having a flat surface facing the substrate. Thus, the flat backside surface of the substrate 8 is clamped against the flat surface of the optic flat.

As shown in FIG. 7C, when the compressed gas is released from the chamber 754 back into the source 750 (i.e., when the bladder is deflated) via the piping 752 or into the ambient, the movable member 705 (e.g., the flexible membrane) moves downward toward the inner volume of the chamber 754. This releases the substrate 8 from being pressed against the optically transparent mechanical stop 802. This allows the substrate 8 and the backplane 32 to be moved laterally relative to the optically transparent mechanical stop 802, as described in more detail below.

The movable member 705 (e.g., the flexible membrane) may have any suitable shape. For example, as shown in FIG. 7D, the movable member 705 may have a shape of a rectangle (e.g., square) which is mounted in a circular rigid frame 756. The square may have an area which is similar to (i.e., within 20% of) the area of the LED die 110. The movable member 705 may comprise an elastomer flexible membrane (i.e., an elastomer diaphragm) mounted in a metal frame 756.

Returning to FIG. 7A, the first structural member 702a may include a first planar surface 708a spanning a first length (e.g., along the x-direction in FIG. 7A) and a first width (e.g., along the y-direction in FIG. 7A) such that the first length is greater than the first width. Similarly, the second structural member 702b may include a second planar surface 708b spanning a second length (e.g., also along the x-direction in FIG. 7A) and a second width (e.g., also along the y-direction in FIG. 7A) such that the second length is greater than the second width. Further, the first base member 706a and the second base member 706b rigidly connect the first structural member 702a and the second structural member 702b such that the first planar surface 708a is parallel to the second planar surface 708b and such that the open channel 704 is formed between the first structural member 702a and the second structural member 702b. Further, the width of the channel 704 may extend in a direction parallel to the first length and the second length (i.e., along the x-direction). Also, as shown in FIG. 7A, the channel may have a height that extends along a direction perpendicular to the first planar surface 708a and the second planar surface 708b (i.e., along the z-direction in FIG. 7A).

FIG. 8 is a top view of the an apparatus 800 containing the component 700 of FIG. 7A, according to some embodiments. As shown, the component 700 is configured to receive a substrate 8 and a backplane 32 in the open channel 704 (e.g., see FIG. 7A). The substrate 8 may be positioned relative to the component 700 such that a specific area of the substrate 8 is located under the optically transparent mechanical stop 802. The movable member 705 may then be actuated (i.e., the bladder may be inflated) to thereby clamp the substrate 8 and the backplane 32 to the component 700. As described above, the movable member 705 may be actuated by causing the movable member 705 to expand by introducing compressed gas into the chamber 754 that is configured to receive the compressed gas. The system 800 may further include at least one laser radiation source 912 (e.g., see FIG. 9) that is configured to direct a laser radiation 914 (e.g., see FIG. 9) through the optically transparent mechanical stop 802 to irradiate a portion of the substrate 8, as described in greater detail below.

The movable member 705 may be configured to have a first area that is smaller than a total area of the substrate 8 and the backplane such that the movable member 705 is configured to press on the backplane 32 to press a localized area (e.g., a die 110 area) of the substrate 8 against the optically transparent mechanical stop 802. A such, the movable member 705 may be configured to indirectly generate pressure on the substrate 8 over a second area 806 that is smaller than the total area of the substrate 8. The second area 806 may correspond to a single LED die 110 or to a LED coupon 1 or to a region corresponding to a portion of a LED coupon 1. Alternatively, the second area 806 may be larger than a single LED die or coupon and may include an area corresponding to a single LED die or coupon plus an area corresponding to a further LED die or coupon or to a portion of a further LED die or coupon. In this way, the movable member 705 may be configured to generate a uniform pressure on a single LED die or coupon or to an area smaller than or larger than a single LED die or coupon but less than a total area of the substrate 8.

FIG. 9 is a three-dimensional view of the apparatus 800 of FIG. 8, which further includes a movable stage 902, according to some embodiments. The movable stage 902 is attached to the component 700 of FIG. 7A (i.e., to the clamp frame 702a, 702b) and is configured to move the clamp frame in a plane that is parallel to the first surface 708a of the first structural member 702a and parallel to a second planar surface 708b of the second structural member 702b (e.g., see FIG. 7A). In this regard, the apparatus 800 may include an x-stage 904 that is configured to move the component 700 along the x-direction. The apparatus 800 may further include a y-stage 906 configured to move the component 700 along the y-direction, and a z-stage 908 configured to move the component 700 along the z-direction. The apparatus 800 may further include an angular stage (i.e., a tilt stage) 910 that may be configured to change an angular orientation about one or more angles. For example, the angular stage 910 may be configured to adjust a first angle about the x-axis and/or may be configured to adjust a second angle about the y-axis.

As shown in FIG. 9, the movable member 705 may be configured to be located in a portion of the apparatus 800 along with a mounting structure that couples the component 700 to the movable stage 902. Further, as shown in FIGS. 8 and 9, the optically transparent mechanical stop 802 may be configured as a circular window that is supported by the first structural member 702a. In other embodiments, however, the optically transparent mechanical stop 802 may be configured to have various other shapes.

As mentioned above, the apparatus 800 may further include at least one laser radiation source 912 that is configured to direct laser radiation (e.g., UV and/or IR radiation) 914 through the optically transparent mechanical stop 802 to irradiate a portion of the substrate 8. The at least one laser radiation source 912 may comprise any suitable laser, such as one or more fiber lasers. Other laser types may also be used. For example, the at least one laser radiation source 912 may comprise a UV fiber laser 912A and an infrared (IR) fiber laser 912B positioned next to each other over the optically transparent mechanical stop 802. The UV fiber laser 912A may be used for laser lift-off and the infrared fiber laser 912B may be used for bonding, as described above with respect to FIGS. 6B and 6E, respectively.

In one embodiment, the at least one laser radiation source 912 may have a fixed location. The laser radiation 914 may be scanned over a portion of the substrate 8 by using the movable stage 902 to move the rigid structure (i.e., component 700), the backplane 32 and the substrate 8 (e.g., see FIG. 8) clamped by the clamp frame (702a, 702b), relative to the laser radiation source 912A or 912B.

In this embodiment, the backplane 32 and the substrate 8 are inserted into the channel 704 in the clamp frame (702a, 702b) with their respective bonding structures 37 and 17 aligned and facing each other. The bladder 754 is then inflated to raise the diaphragm 705 against the back of the backplane 32, as shown in FIG. 7B. This presses the backside of the substrate against the optic flat 802, and clamps the backplane 32 and substrate 8 in the clamp frame (702a, 702b), such that an LED die 110 is located below the optic flat. The x-stage 904 and the y-stage 906 are then moved in respective x and y directions to raster the laser radiation 914 emitted by the at least one laser radiation source 912 along the backside of the LED die 110 to perform either the laser lift-off shown in FIG. 6B or laser bonding shown in FIG. 6E by. After the laser lift-off and laser bonding steps are performed on the selected LED die 110, the bladder 754 is deflated and the substrate 8 is released from contact with the optic flat 802, as shown in FIG. 7C.

The backplane 32 and substrate 8 are then indexed (i.e., moved) relative to the optic flat 802 such that a different second LED die 110 is located between the diaphragm 705 and the optic flat 802. The indexing may be conducted by moving the backplane 32 and substrate relative the clamp frame (702a, 702b) and/or by moving the diaphragm 705 and bladder 754 relative to the optic flat 802. The relative displacement corresponds to a pitch of the LED die 110 or coupon 1. In this way, individual LED dies 110 or coupons 1 may be sequentially irradiated with the laser radiation 914. The process described above is then repeated for the second die and so on for all LED dies on the substrate.

In one alternative embodiment, instead of the at least one laser source being stationary, the at least one laser source 912 may be moved relative to the substrate 8 and the optic flat 802 instead of or in addition to moving the x-stage 904 and/or the y-stage 906 to raster the laser radiation 914 across the LED die 110. In another alternative embodiment, rather than moving the at least one laser source 912, the laser radiation 914 is rastered across the backside of the substrate 8 by using one or more movable mirrors or other beam deflection optics which deflects the laser radiation 914 beam, instead of or in addition to moving the x-stage 904 and/or the y-stage 906.

The apparatus 800 may be configured to be lightweight due to its shape, thus providing fast, automated x-y stage motion for laser rastering, as well as for step-and-repeat translations until the entire substrate 8 is fully processed. For example, the substrate 8 may be clamped such that a first LED die 110 may be scanned. The system may then irradiate a first plurality of LEDs of the first LED die 110 on the substrate 8. The moveable member 705 may then be deactivated to remove the force pressing the substrate 8 against the optically transparent mechanical stop 802. The substrate 8 may then be moved relative to the apparatus 800 and the movable member 705 may then be reactivated. By reactivating the movable member 705, the substrate 8 may then be re-clamped in the clamp frame. A second plurality of LEDs on a second LED die 110 of the substrate 8 may then be irradiated. The apparatus 800 thus allows the substrate 8 to have ample clearance to freely move about in the x-y plane and to incrementally apply highly concentrated and uniform pressure to the area being processed. As such, small areas of a larger substrate may be sequentially processed without the need to dice the substrate 8 or the backplane 32. In one embodiment, the apparatus 800 may be configured to handle substrates and backplanes up to 12 inches in diameter. The entire apparatus 800 may be configured to move together with the substrate 8 during laser rastering, and the substrate 8 may be free to be indexed and clamped with a step-and-repeat sequence.

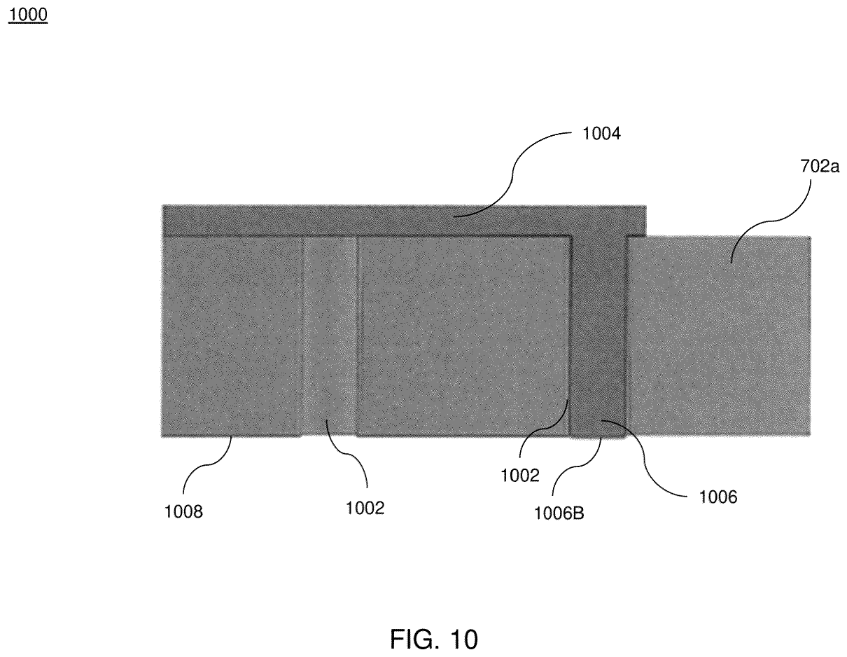

FIG. 10 is a vertical cross-sectional view of a portion of a pin release mechanism 1000, according to some embodiments. In this regard, a portion of the first structural member 702a may further be configured to include one or more holes 1002. On or more movable masses 1004 having a pin-shaped member 1006 are provided. Each pin-shaped member 1006 is located in the respective hole 1002. In this way, the pin release mechanism 1000 uses gravity to apply a light counter force to the backside of the substrate 8 to thereby overcome surface tension and facilitate gentle release of the substrate 8 from the optically transparent mechanical stop 802 after the bladder 754 is deflated, as shown in FIG. 7C.

When the bladder 754 is inflated, the backside of the substrate 8 pushes up on the pin-shaped member 1006, such that the bottom surface 1006B of the pin-shaped member is raised even with the horizontal plane 1008, which corresponds to the bottom surface of the optically transparent mechanical stop 802 and the bottom surface of member 702b. When the bladder 754 is deflated, the pin-shaped member 1006 pushes down on the backside of the substrate 8 by the force of gravity to overcome the force of surface tension and to release the backside of the substrate 8 from the optically transparent mechanical stop 802. In this position, the bottom surface 1006B of the pin-shaped member 1006 is located below the horizontal plane 1008.

In this way, a movable mass (1004, 1006) formed in the first structural member 702a may be configured to impart a second force on the second side (e.g., top side) of the substrate 8 such that the second force is in an opposite direction to the first force (i.e., the force generated by the movable member 705). The second force may have a magnitude that is less than a first magnitude of the first force. In this way, the second force does not impede the action of the movable member 705 in forcing the substrate 8 against optically transparent mechanical stop 802. However, when the first force is removed by de-activating the movable member 705 (e.g., by deflating the bladder 754), the second force generated by the movable mass (1004, 1006) is configured to overcome surface tension and to cause a release of the substrate 8 from the optically transparent mechanical stop 802. In various embodiments, the movable mass (1004, 1006) may generate an adjustable force. In this regard, the force may be adjusted by varying the number of pins used or by increasing or decreasing a mass associated with one or more pins.

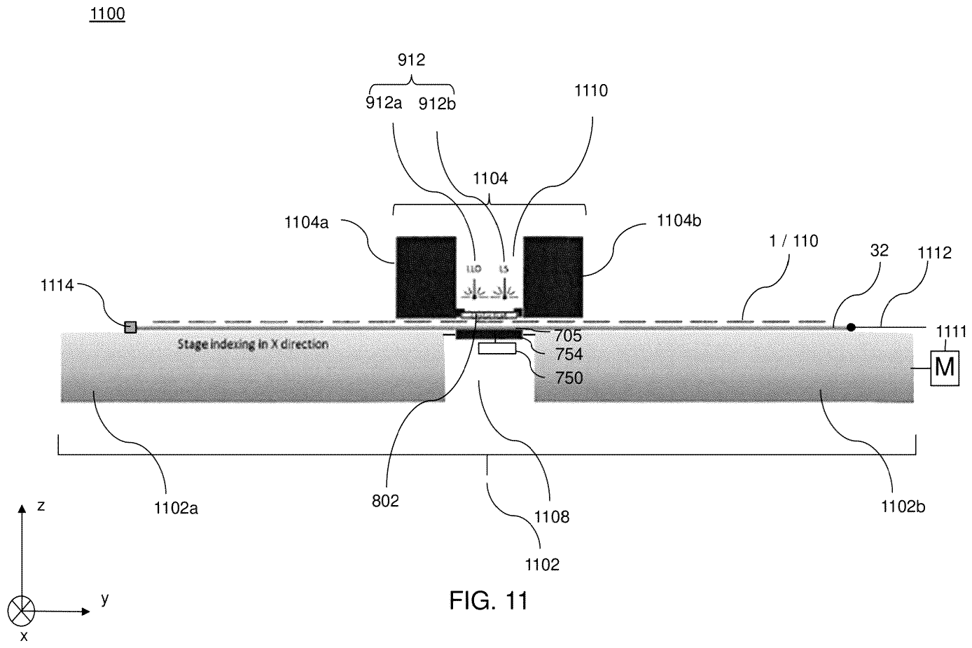

FIG. 11 is a vertical cross-sectional view of a further apparatus 1100 for transferring light-emitting diodes, according to a second embodiment. The apparatus 1100 may be used to transfer LEDs 10 from coupons 1 or dies 110 to a large area backplane 32, such as a LTPS backplane. The LTPS backplane may comprise a large area glass substrate containing bonding structures 37 and low temperature polycrystalline silicon (i.e., “LTPS”) driver circuitry (e.g., thin film transistors (“TFTs”)) on its top surface. The TFTs are typically formed at temperatures below 650 degrees Celsius to avoid damaging the glass backplane substrate.

The apparatus 1100 may include a first support structure 1102 configured to support the large area backplane 32, such as the LTPS backplane with plural LED coupons 1 or LED dies 110 “flip-chipped” onto the backplane 32. In other words, the LED coupons or dies are flipped over such that their bonding structures 17 are located on the respective bonding structures 37 on the backplane, as described above with respect to FIG. 6A.

The apparatus 1100 may include the above described movable member 705 supported by the first support structure 1102, and a second support structure 1104 located above the first support structure 1102. The apparatus 1100 may further include the above described optically transparent mechanical stop (e.g., the optical flat) 802 supported by the second support structure 1104.

The apparatus 1100 may be configured to hold the backplane 32 and the substrate 8 in a space between the first support structure 1102 and the second support structure 1104 and to rigidly clamp the backplane 32 and the substrate 8 by generating a pressure on the movable member 705 to clamp the substrate 8 against the optically transparent mechanical stop 802, as described. The apparatus 1100 allows for much larger backplane sizes, (e.g., such as Gen 10 glass panels having a size of at least one meter).

The apparatus 1100 may further include the at least one laser radiation source 912 (e.g., UV laser source 912a and IR laser source 912b) that is configured to direct the laser radiation 914 (e.g., see FIG. 9) through the optically transparent mechanical stop 802 to irradiate the LED coupon 1 or LED die 110. The at least one laser radiation source 912 may comprise one or more movable fiber laser sources which move in the x-y plane to raster the laser radiation on the backside of the substrate 8 of the LED coupon or die. Alternatively one or more movable mirrors or other beam deflection optics which deflects the laser radiation 914 beam may be used instead. In this way, the apparatus 1100 may remain stationary while the laser rasters over a single LED coupon or die. Then, as in previously-described embodiments, the force generated by the movable member 705 may be released to allow the substrate 8 of the coupon or die to be un-clamped from the optic flat 802. The backplane 32 and may then be moved so that another coupon or die may be processed. In this way, the backplane 32 supporting the LED coupons or dies may be free to be indexed and clamped with a step-and-repeat sequence until all LED coupons or dies have been processed.

The movable member 705 may be configured as described above with reference to previous embodiments. In this regard, the apparatus 1100 may further include a source of a compressed gas 750 and a chamber (e.g., bladder) 754 configured to receive the compressed gas. The movable member 705 may include a flexible membrane (e.g., diaphragm) covering a wall of the chamber 754 such that the flexible membrane is configured to expand in response to the pressure generated by the compressed gas when the compressed gas is introduced into the chamber 754. An expansion of the flexible membrane may cause the flexible membrane to press against the bottom of the backplane 32.

As shown in FIG. 11, the first support structure 1102 may be configured as a stage having a first slab 1102a separated from a second slab 1102b along a length direction (e.g., along the y-direction) thereby forming a first volume 1108 along the width direction (e.g., along the x-direction, that is, into the plane of the figure) between the first slab 1102a and the second slab 1102b. The first and second slabs 1102a and 1102b may comprise granite slabs or slabs of other suitable material. The movable member 705 may be located in the first volume 1108 and may be supported by the first support structure 1102 by various mechanical support structures.

The second support structure 1104 may be configured as a gantry having two parallel elongated members (1104a, 1104b) having a common width direction (e.g., the x-direction) such that a second volume 1110 is formed between the elongated members 1104a and 1104b. For example, the second support structure 1104 having first and second elongated ribs 1104a and 1104b may comprise a granite arch or another material arch that forms the gantry. The optically transparent mechanical stop 802 may be located in the second volume 1110 and may be supported by the second support structure 1104 by various mechanical support structures (not shown).

As with previous embodiments, described above, the movable member 705 may have a first area that is smaller than a total area of the backplane 32 such that the movable member 705 is configured to press on the backplane 32 to thereby generate the pressure on the backplane 32 over a second area that is smaller than the total area of the backplane 32. In this way, pressure may be applied to an area of the backplane 32 corresponding to a single LED coupon 1 or a single LED die 110.

The stage 1102 may be indexed along the x-direction by a motor 1111 configured to move the stage along the x-direction, while the backplane 32 may be indexed along the y-direction by a movable actuator 1112 (e.g., a gripper or another suitable moving device, such as a push rod) once the bladder 754 is deflated. This allows different LED coupons or dies to be indexed below the optical flat 802 while the bladder is deflated. Optionally, the backplane 32 may be clamped to the stage 1102 by one or more releasable clamps 1114 while the bladder 754 is inflated during the laser processing. The clamps 1114 are released while the actuator 1112 is moving the backplane 32 over the stage 1102.

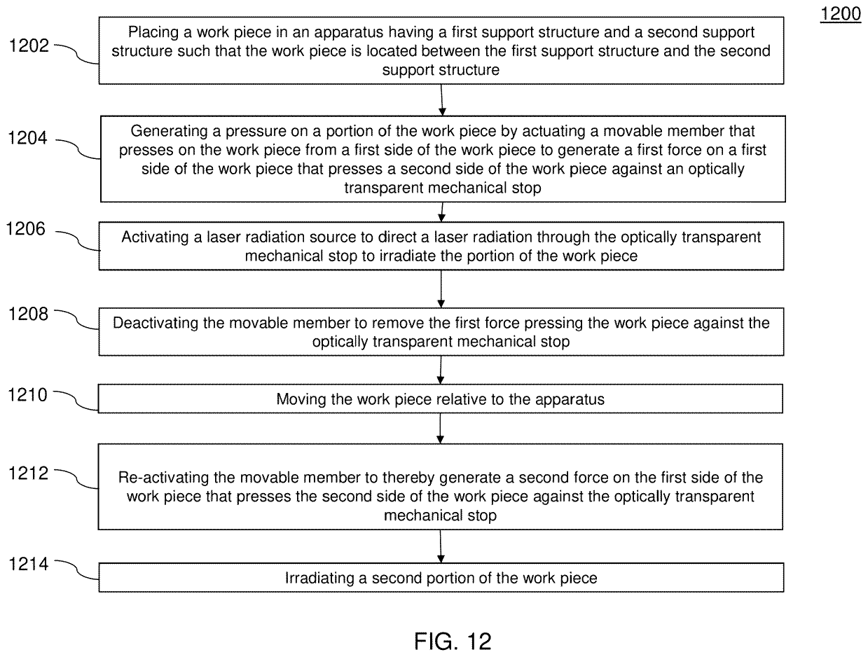

FIG. 12 illustrates a flowchart illustrates various operations in a method 1200 of transferring LEDs, according to some embodiments. In operation 1202, the method 1200 may include placing a work piece (8, 32) in an apparatus (800, 1100) including a first support structure (702a, 1102) and a second support structure (702b, 1104) such that the work piece (8, 32) is located between the first support structure (702a, 1102) and the second support structure (702b, 1104). In operation 1204, the method 1200 may include generating a pressure on a portion of the work piece (8, 32) by actuating a movable member 705 that presses on the work piece (8, 32) from a first side of the work piece (8, 32) to generate a first force on a first side of the work piece (8, 32) that presses a second side of the work piece (8, 32) against an optically transparent mechanical stop 802. In operation 1206, the method 1200 may include activating a laser radiation source (912, 912a, 912b) to direct a laser radiation 914 through the optically transparent mechanical stop 802 to irradiate the portion of the work piece (8, 32). In operation 1208, the method 1200 may include deactivating the movable member 705 to remove the first force pressing the work piece (8, 32) against the optically transparent mechanical stop 802. In operation 1210, the method 1200 may include moving the work piece (8, 32) relative to the apparatus (800, 1100). In operation 1212, the method 1200 may include re-activating the movable member 705 to thereby generate a second force on the first side of the work piece (8, 32) that presses the second side of the work piece (8, 32) against the optically transparent mechanical stop 802. In operation 1212, the method 1200 may include irradiating a second portion of the work piece (8, 32).

Disclosed embodiments may be advantageous in that they may be used to process any type of LED substrate, such as sapphire or silicon, and any type of backplane substrate material, LTPS or CMOS, regardless of the CTE mismatch. The backplane substrate size may be limited only by the size of the system, as opposed to any process limitation. The type of laser processing can also be readily varied, such as different wavelengths, laser lift off, laser soldering, laser annealing, etc. The configuration of the movable member 705 may allow very precise control of the applied pressure and may ensure that the force distribution is uniform, regardless of substrate thickness non-uniformity or flatness aberrations in the optic flat.

Although the foregoing refers to particular preferred embodiments, it will be understood that the invention is not so limited. It will occur to those of ordinary skill in the art that various modifications may be made to the disclosed embodiments and that such modifications are intended to be within the scope of the invention. Where an embodiment employing a particular structure and/or configuration is illustrated in the present disclosure, it is understood that the present invention may be practiced with any other compatible structures and/or configurations that are functionally equivalent provided that such substitutions are not explicitly forbidden or otherwise known to be impossible to one of ordinary skill in the art.

What is claimed is:

1. An apparatus, comprising:
a rigid structure comprising a first structural member supported above a second structural member thereby forming an open channel;
an optically transparent mechanical stop supported by the first structural member;
at least one laser radiation source positioned to provide laser radiation through the optically transparent mechanical stop; and
a movable member supported by the second structural member,
wherein the rigid structure is configured to receive a work piece in the open channel and to clamp the work piece by generating a pressure on the movable member such that the movable member presses on the work piece from a first side of the work piece to generate a first force on the first side of the work piece that presses a second side of the work piece against the optically transparent mechanical stop.

2. The apparatus of claim 1, further comprising:
a source of a compressed gas; and
a chamber configured to receive the compressed gas.

3. The apparatus of claim 2, wherein:
the chamber comprises a bladder;
the movable member comprises flexible membrane located on a wall of the bladder;
the flexible membrane is configured to expand in response to pressure generated by the compressed gas when the compressed gas is introduced into the bladder; and
the expansion of the flexible membrane causes the flexible membrane to press against the first side of the work piece.

4. The apparatus of claim 1, wherein the movable member comprises a first area that is smaller than a total area of the work piece such that the movable member is configured to press on the work piece to thereby generate the pressure on the work piece over a second area that is smaller than the total area of the work piece.

5. The apparatus of claim 4, wherein:
the work piece comprises a backplane supporting plural LED dies on a substrate; and
the second area corresponds to an area of one of the LED dies such that the movable member is configured to generate a uniform pressure on the LED die.

6. The apparatus of claim 1, wherein the rigid structure comprises a clamp frame.

7. The apparatus of claim 6, wherein:
the first structural member comprises a first planar surface spanning a first length and a first width such that the first length is greater than the first width; and
the second structural member comprises a second planar surface spanning a second length and a second width such that the second length is greater than the second width.

8. The apparatus of claim 7, further comprising a support structure which rigidly connects to the first structural member and the second structural member at respective first ends and second ends of the first structural member and the second structural member such that the first planar surface is parallel to the second planar surface and such that the open channel is formed between the first planar surface and the second planar surface, wherein a width of the open channel extends along a direction parallel to the first length and the second length.

9. The apparatus of claim 7, further comprising a movable stage that is attached to the clamp frame and that is configured to move the clamp frame in a plane that is parallel to a first surface of the first structural member and parallel to a second surface of the second structural member.

10. The apparatus of claim 9, wherein:
the at least one laser radiation source has a fixed location that is configured to direct the laser radiation through the optically transparent mechanical stop to irradiate a portion of the work piece; and
the movable stage is configured to move the clamp frame and the work piece clamped by the clamp frame relative to the laser radiation source.

11. The apparatus of claim 10, wherein the movable stage is configured to move the clamp frame and the work piece by displacements that correspond to a pitch of an LED die.

12. The apparatus of claim 1, further comprising a movable mass formed on the first structural member and configured to impart a second force on the second side of the work piece such that the second force is in an opposite direction to the first force and has a second magnitude that is less than a first magnitude of the first force.

13. The apparatus of claim 12, wherein the second force is generated by gravity and is configured to overcome surface tension and to cause a release of the work piece from the first structural member after removing the first force generated by the movable member.

14. The apparatus of claim 1, wherein:
the first structural member comprises a stage; and
the second structural member comprises a gantry.

15. The apparatus of claim 14, wherein:
the stage comprises a first slab separated from a second slab along a length direction thereby forming a first volume along a width direction between the first slab and the second slab; and
the movable member is located in the first volume.

16. The apparatus of claim 15, wherein:
the gantry comprises two parallel elongated members comprising a common width direction such that a second volume is formed along the common width direction; and
the optically transparent mechanical stop is located in the second volume.

17. The apparatus of claim 16, further comprising:
a motor configured to move the stage in a first direction; and
an actuator configured to move the work piece in the second direction perpendicular to the first direction between the stage and the gantry.

18. A method, comprising:
placing a work piece in an apparatus comprising a first support structure and a second support structure such that the work piece is located between the first support structure and the second support structure;
generating a pressure on a portion of the work piece by actuating a movable member that presses on the work piece from a first side of the work piece to generate a first force on a first side of the work piece that presses a second side of the work piece against an optically transparent mechanical stop; and
directing laser radiation through the optically transparent mechanical stop to irradiate the portion of the work piece.

19. The method of claim 18, wherein:
the work piece comprises a backplane located on the movable member and plural light emitting diode (LED) dies or coupons located on the backplane;
the laser radiation comprises UV laser radiation which lifts-off one or more LEDs from a substrate of one of the LED dies or coupons and infrared laser radiation which laser bonds the one or more LEDs to bonding structures on the backplane;
the movable member comprises a bladder having a flexible diaphragm;
when the bladder is filled with pressurized gas, the flexible diaphragm presses on the backplane from the first side of the backplane which presses the second side of at least one of the LED dies or coupons against the optically transparent mechanical stop; and
when the pressurized gas is released from the bladder, the flexible diaphragm does not press on the backplane which releases the at least one of the LED dies or coupons from contact with the optically transparent mechanical stop.

20. The method of claim 19, further comprising:
irradiating with the laser radiation a first plurality of LEDs of a first LED die or coupon of the plural LED dies or coupons;
deactivating the movable member to remove the first force pressing the first LED die or coupon against the optically transparent mechanical stop;
moving the work piece relative to the apparatus;
re-activating the movable member to thereby generate a second force on the first side of the backplane that presses a second LED die or coupon of the plural LED dies or coupons against the optically transparent mechanical stop; and
irradiating with the laser radiation a second plurality of LEDs of the second LED die coupon.
